(19) United States
(12) Patent Application Publication
(10) Pub. No.: US 2023/0223363 A1
(43) Pub. Date: Jul. 13, 2023

(54) HIGH FREQUENCY CIRCUIT

(71) Applicant: Mitsubishi Electric Corporation, Tokyo (JP)

(72) Inventors: Yuta SUGIYAMA, Tokyo (JP); Hidenori ISHIBASHI, Tokyo (JP); Toru TAKAHASHI, Tokyo (JP)

(73) Assignee: Mitsubishi Electric Corporation, Tokyo (JP)

(21) Appl. No.: 18/185,627

(22) Filed: Mar. 17, 2023

Related U.S. Application Data
(63) Continuation of application No. PCT/JP2020/040165, filed on Oct. 27, 2020.

(51) Int. Cl. H01L 23/66; H01L 23/00; H01L 23/34; H01L 23/48

(52) U.S. Cl. CPC H01L 23/66; H01L 24/48; H01L 23/345; H01L 28/20; H01L 23/481; H01L 28/40; H01L 2924/30111; H01L 2924/1421; H01L 2223/6611; H01L 2223/6616

(57) ABSTRACT

A high frequency circuit includes: a first wire provided on a front surface of a board and being in contact with a heat generation part; a second wire provided on the front surface of the board and connected to ground; and a chip resistor connected between the first wire and the second wire and having a thermal conductive characteristic and an electric insulation characteristic, and the first wire includes: a wire part which is disposed between the heat generation part and the chip resistor, and which has a characteristic impedance equal to an impedance as a reference for impedance matching in the first wire; and a wire part which is disposed on a low temperature side with the chip resistor being set as a boundary, and which has a thermal resistance higher than that of the chip resistor.

### CROSS REFERENCE TO RELATED APPLICATIONS

This application is a Continuation Application of PCT International Application No. PCT/JP2020/040165, filed on Oct. 27, 2020, all of which is hereby expressly incorporated by reference into the present application.

### TECHNICAL FIELD

The present disclosure relates to a high frequency circuit.

### BACKGROUND ART

In Patent Literature 1, a high frequency circuit is disclosed.

### CITATION LIST

### Patent Literature

Patent Literature 1: JP 2017-59884 A

### SUMMARY OF INVENTION

### Technical Problem

The high frequency circuit disclosed in Patent Literature 1 electrically connects a first signal transmission line on a high temperature side and a second signal transmission line on a low temperature side by means of a third signal transmission line having a heat insulating property. Therefore, the high frequency circuit disclosed in Patent Literature 1 reduces the heat conduction between the first signal transmission line and the second signal transmission line.

However, the high frequency circuit disclosed in Patent Literature 1 can reduce the propagation of the heat, but does not take heat dissipation characteristics into consideration. Therefore, in the high frequency circuit disclosed in Patent Literature 1, there is a possibility that the temperature of the first signal transmission line on the high temperature side rises, so that the first signal transmission line undergoes thermal degradation.

The present disclosure is made in order to solve the above-mentioned problem, and it is therefore an object of the present disclosure to provide a high frequency circuit that can improve the heat dissipation characteristics of wires.

### Solution to Problem

A high frequency circuit according to the present disclosure includes: a first wire provided on a front surface of a board and being in contact with a heat generation part; a second wire provided on the front surface of the board and connected to ground; and a chip component connected between the first wire and the second wire and having a thermal conductive characteristic and an electric insulation characteristic, and the first wire includes: a high temperature side wire part which is disposed between the heat generation part and the chip component, and which has a characteristic impedance equal to an impedance as a reference for impedance matching in the first wire; and a low temperature side wire part which is disposed on a low temperature side with the chip component being set as a boundary, and which has a thermal resistance higher than that of the chip component.

### Advantageous Effects of Invention

According to the present disclosure, the heat dissipation characteristics of the wires can be improved.

### BRIEF DESCRIPTION OF DRAWINGS

FIG. 1 is a diagram showing the configuration of a high frequency circuit according to Embodiment 1;

FIG. 2 is a cross-sectional view of FIG. 1 taken along line II-II;

FIG. 3 is a diagram showing the configuration of a high frequency circuit according to Embodiment 2;

FIG. 4 is a diagram showing the configuration of a high frequency circuit according to Embodiment 3;

FIG. 5 is a diagram showing the configuration of a high frequency circuit according to Embodiment 4;

FIG. 6 is a diagram showing the configuration of a high frequency circuit according to Embodiment 5;

FIG. 7 is a diagram showing the configuration of a high frequency circuit according to Embodiment 6;

FIG. 8 is a diagram showing the configuration of a high frequency circuit according to Embodiment 7;

FIG. 9 is a diagram showing the configuration of a high frequency circuit according to Embodiment 8;

FIG. 10 is a diagram showing the configuration of a high frequency circuit according to Embodiment 9;

FIG. 11 is a diagram showing the configuration of a high frequency circuit according to Embodiment 10; and

FIG. 12 is a diagram showing the configuration of a high frequency circuit according to Embodiment 11.

### DESCRIPTION OF EMBODIMENTS

Hereinafter, in order to explain the present disclosure in greater detail, embodiments of the present disclosure will be explained with reference to the accompanying drawings.

### Embodiment 1

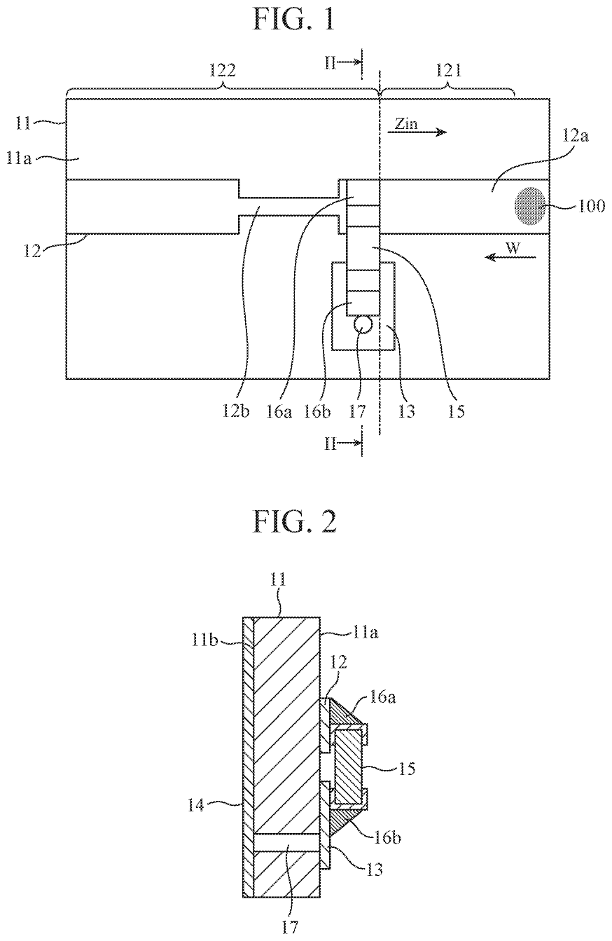

A high frequency circuit according to Embodiment 1 will be explained using FIGS. 1 and 2. FIG. 1 is a diagram showing the configuration of the high frequency circuit according to Embodiment 1. FIG. 2 is a cross-sectional view of FIG. 1 taken along line II-II.

As shown in FIGS. 1 and 2, the high frequency circuit according to Embodiment 1 includes a board 11, a wire 12 which is a first wire, a wire 13 which is a second wire, a ground wire 14, a chip resistor 15 which is a chip component, solder parts 16a and 16b, and a via 17.

The board 11 is made of a resin, and is formed of, for example, a substrate material such as alumina or aluminum nitride. This board 11 has a front surface 11a and a rear surface 11b.

The wire 12 is provided on the front surface 11a of the board 11. This wire 12 is connected to, for example, a heat generation part 100 such as an electronic component, and transmits high-frequency power. An arrow W shown in FIG. 1 shows a direction of transmission of the high-frequency power.

The wire 12 has a wire part 12a and a thin wire part 12b. The wire part 12a is disposed on a high temperature side 121 of the wire 12 with the chip resistor 15 being set as a boundary. The thin wire part 12b is disposed on a low temperature side 122 of the wire 12 with the chip resistor 15 being set as a boundary. The details of the chip resistor 15 will be mentioned later.

The wire part 12a constitutes a high temperature side wire part. To this wire part 12a is connected the heat generation part 100. The wire part 12a has a characteristic impedance equal to an impedance which is a reference for impedance matching in the wire 12.

The thin wire part 12b constitutes a low temperature side wire part. This low temperature side wire part has a thermal resistance higher than that of the chip resistor 15. The width of the thin wire part 12b is narrower than that of the wire part 12a. More specifically, the cross-sectional area of the thin wire part 12b is smaller than that of the wire part 12a. Because the thin wire part 12b is thus formed in such a way as to have a narrow width, the thin wire part has a series inductive characteristic. The series inductive characteristic shows that its high frequency characteristics are the same as those in the case where a coil (inductive reactance) is disposed in series between an input and an output in the wire 12.

The wire 13 is provided on the front surface 11a of the board 11. The ground wire 14 is provided on the rear surface 11b of the board 11. The via 17 penetrates the board 11 between the front surface 11a and the rear surface 11b, and is connected to the wire 13 and the ground wire 14. More specifically, the wire 13 and the ground wire 14 are connected electrically and thermally by the via 17. The ground wire 14 is kept at a temperature lower than that of the heat generation part 100 by a radiation means (not illustrated).

The chip resistor 15 has a high resistance. This chip resistor 15 has a thermal conductive characteristic sufficiently higher than that of the material of the board, and its main material is a material having an electric insulation characteristic, such as alumina or aluminum nitride. The chip resistor 15 configured in this way is connected between the wire part 12a of the wire 12 and the wire 13. Concretely, an end of the chip resistor 15 is connected to the low temperature side 122 of the wire 12 via the solder part 16a. The other end of the chip resistor 15 is connected to the wire 13 via the solder part 16b.

The resistance value of the chip resistor 15 is sufficiently larger than that of the input impedance Zin of the high temperature side wire part. For example, in the case where the characteristic impedance of the wire part 12a is 50 Ω, the resistance value of the chip resistor 15 ranges from 1 kΩ to 100 MΩ.

Here, the high-frequency power passing through the wire 12 hardly flows through the chip resistor 15 with high-resistance. In the high frequency circuit, for the sake of improving the high-frequency power pass characteristics, for example, it is conceivable that a matching circuit for matching the impedance is provided. At that time, the impedance of the matching circuit is matched to 50 Ω. However, in a case where a thin wire having a series inductive characteristic, out of wires needed for the matching circuit, is disposed between the chip resistor 15 and the heat generation part 100, the heat of the heat generation part 100 is hard to propagate to the chip resistor 15 as compared with a case where a wire having a characteristic impedance of 50 Ω is disposed between them, so that the heat dissipation characteristics of the wire 12 are reduced.

Accordingly, in the high frequency circuit according to Embodiment 1, the thin wire part 12b having a series inductive characteristic, out of the wires needed for the impedance matching, is disposed on the low temperature side 122 of the wire 12 with the chip resistor 15 with high-resistance being set as a boundary. Although the chip resistor 15 divides the wire 12 into the high temperature side 121 including the wire part 12a and the low temperature side 122 including the thin wire part 12b, the connection position of the chip to the wire 12 is placed on the low temperature side 122.

Therefore, in the high frequency circuit, since the thin wire part 12b is disposed on the low temperature side 122 of the wire 12 with the chip resistor 15 being set as a boundary, it is possible to propagate the heat from the high temperature side 121 (heat generation part 100) of the wire 12 to the chip resistor 15. Therefore, the high frequency circuit can propagate the heat propagated to the chip resistor 15 to the ground wire 14 via the wire 13 and the via 17. More specifically, the high frequency circuit transmits the high-frequency power using the wire 12, while making it possible to efficiently release the heat of the wire 12 heated by the heat generation part 100 to the ground wire 14. The high frequency circuit can be used in circuits each having a wire through which a direct current flows.

Further, although the above-mentioned high frequency circuit includes the chip resistor 15 as the chip component, the chip component may be a chip capacitor whose main material is the same as that of the chip resistor 15. In the case where the chip component is a chip capacitor, as mentioned above, the capacitance of the chip capacitor is set to be smaller than that of the wire 12. The capacitance of this wire 12 does not exert any influence on the characteristic impedance of the wire 12. Therefore, the influence of the capacitance of the chip capacitor on the high-frequency power is small, and the high frequency circuit can give off the heat of the wire 12 to the ground wire 14 via the chip capacitor.

As mentioned above, the high frequency circuit according to Embodiment 1 includes: the wire 12 provided on the front surface 11a of the board 11 and being in contact with the heat generation part 100; the wire 13 provided on the front surface 11a of the board 11 and connected to ground; and the chip component connected between the wire 12 and the wire 13 and having a thermal conductive characteristic and an electric insulation characteristic, and the wire 12 includes: the high temperature side wire part which is disposed between the heat generation part 100 and the chip component, and which has a characteristic impedance equal to an impedance as a reference for the impedance matching in the wire 12; and the low temperature side wire part which is disposed on the low temperature side 122 with the chip component being set as a boundary, and which has a thermal resistance higher than that of the chip component. Therefore, the high frequency circuit can improve the heat dissipation characteristics of the wire 12.

In the high frequency circuit, the low temperature side wire part includes the thin wire part 12b which is formed in such a way as to have a width narrower than that of the high temperature side wire part, and which has a series inductive characteristic. Therefore, the high frequency circuit can propagate the heat of the wire 12 to the chip component.

In the high frequency circuit, the chip component is the chip resistor 15. The resistance value of this chip resistor 15 is larger than the value of the input impedance Zin of the high temperature side wire part. Therefore, even though the chip component is the chip resistor 15, the high frequency circuit can propagate the heat of the wire 12 to the chip resistor 15.

In the high frequency circuit, the chip component is the chip capacitor. The capacitance of this chip capacitor is smaller than that of the first wire. Therefore, even though the chip component is the chip capacitor, the high frequency circuit can propagate the heat of the wire 12 to the chip capacitor by making the main material of the chip capacitor be the same as that of the chip resistor 15.

### Embodiment 2

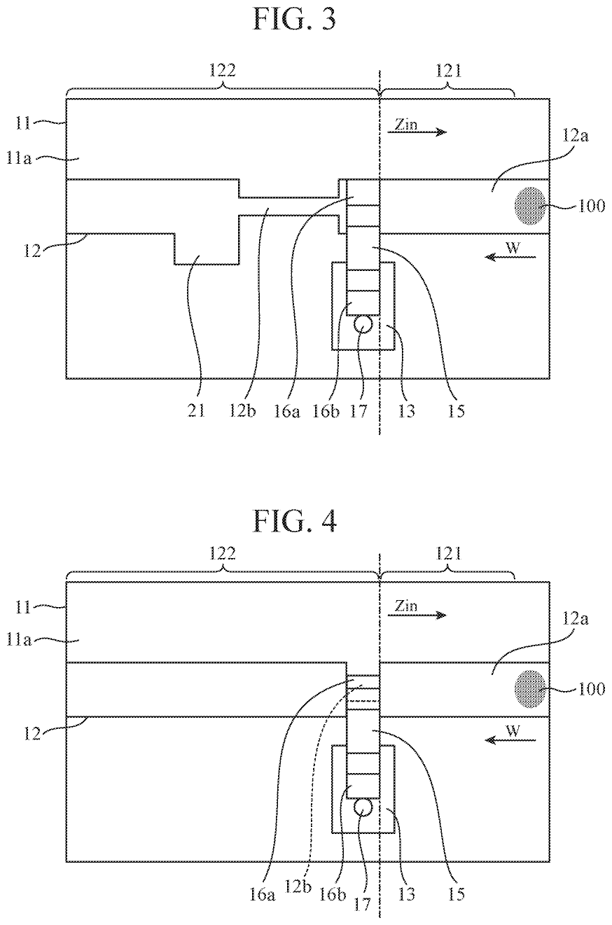

A high frequency circuit according to Embodiment 2 will be explained using FIG. 3. FIG. 3 is a diagram showing the configuration of the high frequency circuit according to Embodiment 2.

As shown in FIG. 3, the high frequency circuit according to Embodiment 2 has a configuration in which a stub 21 is added to the high frequency circuit according to Embodiment 1.

This stub 21 is disposed on a low temperature side 122 of a wire 12. Further, the stub 21 is disposed on a downstream side of a thin wire part 12b in a direction of power transmission. The stub 21 is, for example, an open stub whose base end (branch tip) is in contact with the low temperature side 122 of the wire 12, and whose tip is open. The length of the stub 21 from its base end to its tip is less than or equal to the one-quarter wavelength of high-frequency power transmitted by the wire 12. Because the stub 21 is thus disposed in such a way that the low temperature side 122 of the wire 12 is widen, the stub 21 has a parallel capacitive characteristic. The parallel capacitive characteristic shows that its high frequency characteristics are the same as those in the case where a capacitor (capacitive reactance) is disposed in parallel between the wire 12 and a ground wire 14.

As mentioned above, in the high frequency circuit according to Embodiment 2, the low temperature side wire part includes the stub 21 which is disposed on a downstream side of the thin wire part 12b in the direction of power transmission, and which has a parallel capacitive characteristic. Therefore, the high frequency circuit can improve the heat dissipation characteristics of the wire 12.

### Embodiment 3

A high frequency circuit according to Embodiment 3 will be explained using FIG. 4. FIG. 4 is a diagram showing the configuration of the high frequency circuit according to Embodiment 3.

As shown in FIG. 4, the high frequency circuit according to Embodiment 3 has a configuration in which the position of a thin wire part 12b is changed with respect to the high frequency circuit according to Embodiment 1.

The thin wire part 12b is disposed on a low temperature side 122 of a wire 12. Further, the thin wire part 12b is disposed at a connection position of a chip resistor 15. More specifically, an end of the chip resistor 15 is mounted to the thin wire part 12b via a solder part 16a.

As mentioned above, in the high frequency circuit according to Embodiment 3, the thin wire part 12b of the wire 12 is disposed at the connection position of the chip resistor 15. Therefore, in the high frequency circuit, the heat of the wire 12 propagates to the chip resistor 15 having a high thermal conductive characteristic while avoiding the thin wire part 12b having a high thermal resistance. Therefore, the high frequency circuit can improve the heat dissipation characteristics of the wire 12.

### Embodiment 4

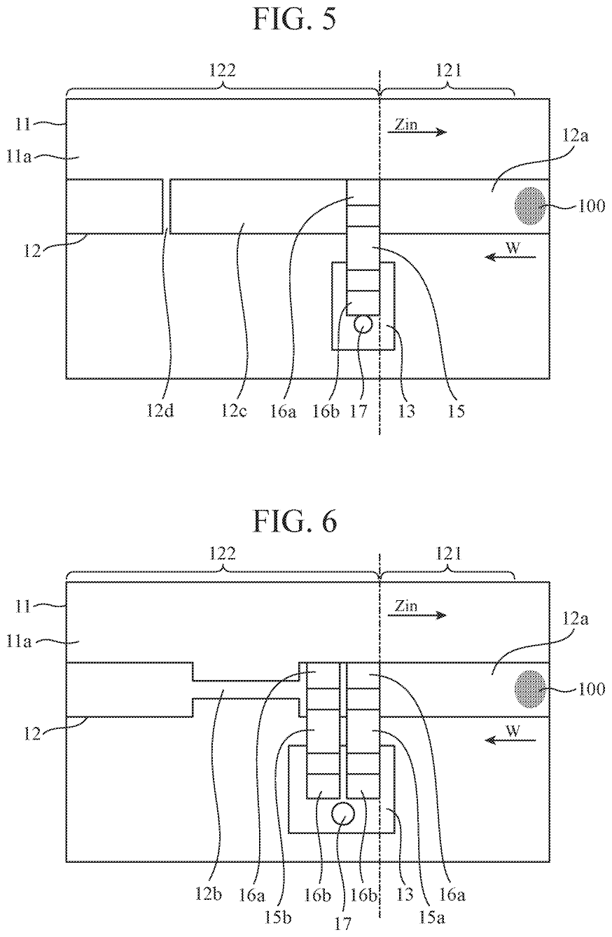

A high frequency circuit according to Embodiment 4 will be explained using FIG. 5. FIG. 5 is a diagram showing the configuration of the high frequency circuit according to Embodiment 4.

As shown in FIG. 5, the high frequency circuit according to Embodiment 4 is configured to include a middle wire part 12c and a disconnection part 12d, instead of the thin wire part 12b of the high frequency circuit according to Embodiment 1. The middle wire part 12c and the disconnection part 12d constitute a low temperature side wire part.

To the middle wire part 12c is connected an end of a chip resistor 15 via a solder part 16a. This middle wire part 12c is formed in such a way as to have a length having a characteristic impedance equal to an impedance which is a reference for impedance matching in a wire 12. Further, the width of a wire part 12a and the width of the middle wire part 12c are the same. More specifically, the cross-sectional area of the wire part 12a and the cross-sectional area of the middle wire part 12c are the same.

The disconnection part 12d has a series capacitive characteristic. This disconnection part 12d is disposed on a downstream side of the middle wire part 12c in a direction of power transmission. The series capacitive characteristic shows that its high frequency characteristics are the same as those in the case where a capacitor (capacitive reactance) is disposed in series between an input and an output of the wire 12.

As mentioned above, in the high frequency circuit according to Embodiment 4, the low temperature side wire part includes: the middle wire part 12c which is formed in such a way as to have a length having a characteristic impedance equal to an impedance as a reference for the impedance matching in the wire 12; and the disconnection part 12d which is disposed on a downstream side of the middle wire part 12c in the direction of power transmission, and which has a series capacitive characteristic. Therefore, the high frequency circuit can improve the heat dissipation characteristics of the wire 12.

### Embodiment 5

A high frequency circuit according to Embodiment 5 will be explained using FIG. 6. FIG. 6 is a diagram showing the configuration of the high frequency circuit according to Embodiment 5.

As shown in FIG. 6, the high frequency circuit according to Embodiment 5 is configured to include multiple chip components. Concretely, while the high frequency circuit according to Embodiment 1 includes the single chip resistor 15, the high frequency circuit according to Embodiment 5 includes multiple chip resistors 15a and 15b. FIG. 6 is an example in which the high frequency circuit according to Embodiment 5 includes two chip resistors 15. The chip resistors 15a and 15b have the same structure and the same function as those of the chip resistor 15.

Each of the chip resistors 15a and 15b is disposed on a low temperature side 122 of a wire 12. Further, the chip resistors 15a and 15b are arranged on an upstream side of a thin wire part 12b in a direction of power transmission. An end of each of the chip resistor 15a and 15b is connected to the wire 12 via a corresponding solder part 16a. The other end of each of the chip resistor 15a and 15b is connected to a single wire 13 via a corresponding solder part 16b.

The chip resistor 15a, out of the chip resistors 15a and 15b, is positioned closest to a heat generation part 100. This chip resistor 15a divides the wire 12 into a high temperature side 121 and the low temperature side 122. More specifically, the high temperature side wire part and the low temperature side wire part are arranged, with the chip resistor 15a which is closest to the heat generation part 100, out of the multiple chip resistors 15a and 15b, being set as a boundary.

Therefore, the high frequency circuit can reduce the thermal resistance from the wire 12 to the wire 13 to about one-half of that in the case where a single chip resistor 15 is included. As a result, the high frequency circuit can propagate more heat of the wire 12 to a ground wire 14.

As mentioned above, the high frequency circuit according to Embodiment 5 includes the multiple chip resistors 15a and 15b, and the high temperature side wire part and the low temperature side wire part are arranged, with the chip resistor 15a which is closest to the heat generation part 100, out of the multiple chip resistors 15a and 15b, being set as a boundary. Therefore, the high frequency circuit can propagate more heat of the wire 12 to the ground wire 14.

### Embodiment 6

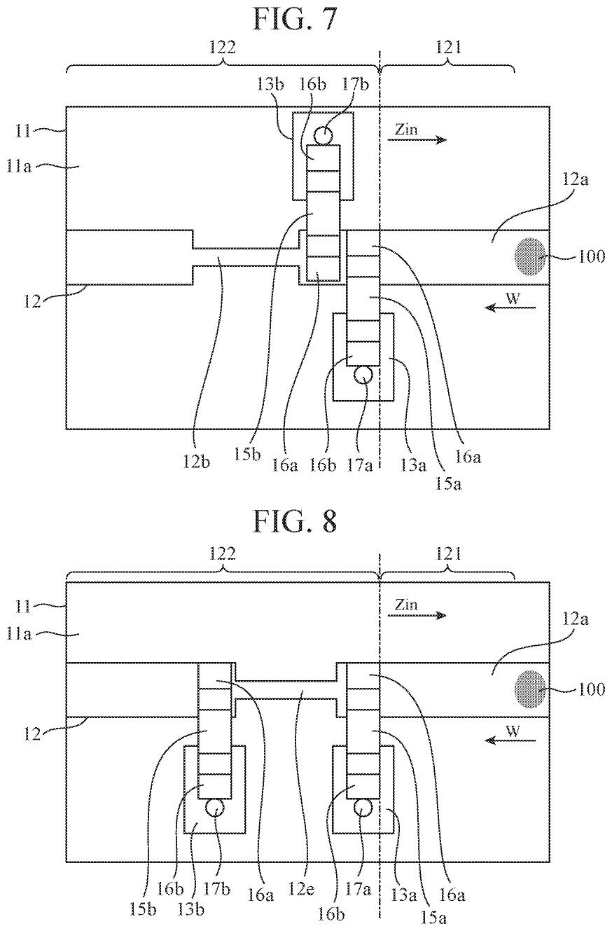

A high frequency circuit according to Embodiment 6 will be explained using FIG. 7. FIG. 7 is a diagram showing the configuration of the high frequency circuit according to Embodiment 6.

As shown in FIG. 7, the high frequency circuit according to Embodiment 6 has a configuration in which the orientation of a chip component is changed with respect to the high frequency circuit according to Embodiment 5.

The high frequency circuit according to Embodiment 6 includes two wires 13a and 13b, two chip resistors 15a and 15b, and two vias 17a and 17b. The wires 13a and 13b have the same structure and the same function as those of the wire 13. Further, the vias 17a and 17b have the same structure and the same function as those of the via 17.

Each of the chip resistors 15a and 15b is disposed on a low temperature side 122 of a wire 12. Further, the chip resistors 15a and 15b are arranged on an upstream side of a thin wire part 12b in a direction of power transmission. The chip resistor 15a is disposed on one side of the wire 12 set as a boundary. The chip resistor 15b is disposed on the other side of the wire 12 set as a boundary. More specifically, the chip resistors 15a and 15b are arranged alternately on the one side and the other side of the wire 12 set as a boundary.

Correspondingly, the wires 13a and 13b are arranged alternately on the one side and the other side of the wire 12 set as a boundary. Further, the vias 17a and 17b are arranged alternately on the one side and the other side of the wire 12 set as a boundary.

An end of the chip resistor 15a is mounted to the wire 12 via a solder part 16a. The other end of the chip resistor 15a is mounted to the wire 13a via a solder part 16b. Further, an end of the chip resistor 15b is mounted to the wire 12 via the solder part 16a. The other end of the chip resistor 15b is mounted to the wire 13b via the solder part 16b.

Therefore, the high frequency circuit can disperse the heat of the wire 12 toward the one side and toward the other side of the wire 12 set as a boundary. As a result, the high frequency circuit can propagate more heat of the wire 12 to a ground wire 14.

As mentioned above, in the high frequency circuit according to Embodiment 6, the multiple chip resistors 15a and 15b are arranged alternately on the one side and the other side of the wire 12 set as a boundary. Therefore, the high frequency circuit can propagate the heat of the wire 12 to the ground wire 14 while dispersing the heat.

### Embodiment 7

A high frequency circuit according to Embodiment 7 will be explained using FIG. 8. FIG. 8 is a diagram showing the configuration of the high frequency circuit according to Embodiment 7.

As shown in FIG. 8, the high frequency circuit according to Embodiment 7 has a configuration in which the high frequency circuit includes an inter-chip thin wire part 12e instead of the thin wire part 12b of the high frequency circuit according to Embodiment 6, and the arrangement of chip resistors 15a and 15b are changed, with respect to the high frequency circuit according to Embodiment 6.

The inter-chip thin wire part 12e constitutes a low temperature side wire part. The width of this inter-chip thin wire part 12e is narrower than that of a wire part 12a. More specifically, the cross-sectional area of the inter-chip thin wire part 12e is smaller than that of the wire part 12a. Because the inter-chip thin wire part 12e is thus formed in such a way as to have a narrow width, the inter-chip thin wire part has a series inductive characteristic.

Each of the chip resistors 15a and 15b is disposed on a low temperature side 122 of a wire 12. The chip resistors 15a and 15b are arranged in such a way as to sandwich the thin wire part 12e therebetween from both sides in a direction of power transmission.

Concretely, the chip resistor 15a is disposed on an upstream side of the inter-chip thin wire part 12e in the direction of power transmission. An end of the chip resistor 15a is mounted to the wire 12 via a solder part 16a. The other end of the chip resistor 15a is mounted to a wire 13a via a solder part 16b. Further, the chip resistor 15b is disposed on a downstream side of the inter-chip thin wire part 12e in the direction of power transmission. An end of the chip resistor 15b is mounted to the wire 12 via the solder part 16a. The other end of the chip resistor 15b is mounted to the wire 13b via the solder part 16b.

Although in FIG. 8 the example in which the chip resistors 15a and 15b are arranged on one side of the wire 12 set as a boundary is shown, each of the chip resistors 15a and 15b may be arranged on either of the one side and the other side of the wire 12 set as a boundary.

As mentioned above, in the high frequency circuit according to Embodiment 7, the low temperature side wire part includes the inter-chip thin wire part 12e which is formed between the adjacent chip resistors 15a and 15b and with a width narrower than that of the high temperature side wire part, and which has a series inductive characteristic. Therefore, the high frequency circuit can propagate the heat of the wire 12 to a ground wire 14 while dispersing the heat.

### Embodiment 8

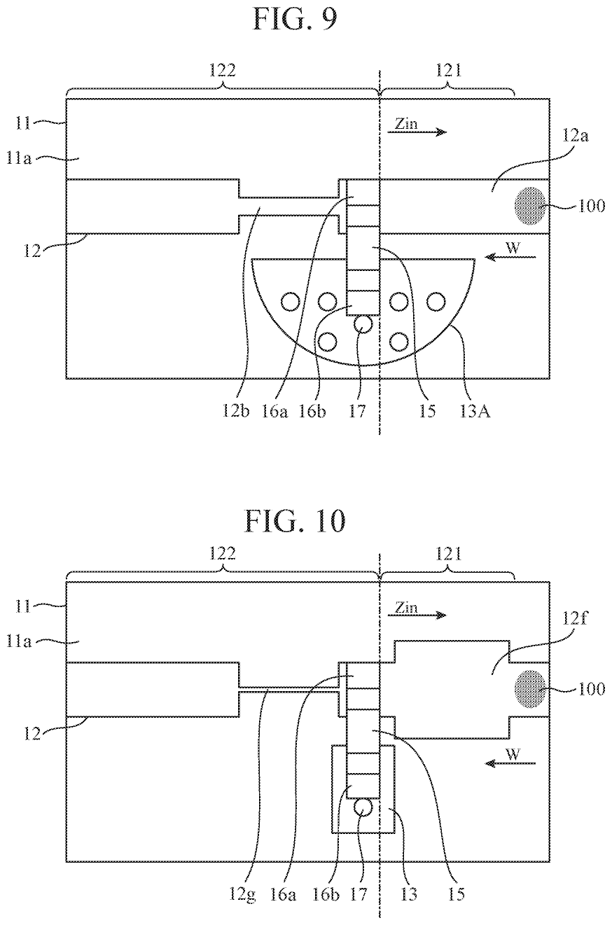

A high frequency circuit according to Embodiment 8 will be explained using FIG. 9. FIG. 9 is a diagram showing the configuration of the high frequency circuit according to Embodiment 8.

As shown in FIG. 9, the high frequency circuit according to Embodiment 8 includes multiple vias 17. More specifically, the high frequency circuit according to Embodiment 1 includes the single via 17 for the single chip resistor 15, whereas the high frequency circuit according to Embodiment 8 includes multiple vias 17 for a single chip resistor 15.

The other end of the chip resistor 15 is mounted to a wire 13A via a solder part 16b. This wire 13A has the same configuration and the same function as those of the wire 13. The vias 17 penetrate a board 11 between a front surface 11a and a rear surface 11b, and are connected to the wire 13A and a ground wire 14. Therefore, the wire 13A and the ground wire 14 are connected electrically and thermally by the vias 17.

At that time, the multiple vias 17 are arranged in such a way as to surround the connection position of the other end of the chip resistor 15. Therefore, the area of the wire 13A is larger than that of the wire 13. This wire 13A has a semicircular shape, for example. Because the high frequency circuit thus includes the multiple vias 17, the high frequency circuit can efficiently propagate the heat of the wire 12 to the ground wire 14.

As mentioned above, the high frequency circuit according to Embodiment 8 includes the ground wire 14 which is provided on the rear surface 11b of the board 11, and the multiple vias 17 which penetrate the board 11 and thermally connect the wire 13A and the ground wire 14. The multiple vias 17 are connected to the wire 13A in such a way as to surround the connection position of the chip resistor 15. Therefore, the high frequency circuit can efficiently propagate the heat of the wire 12 to the ground wire 14.

### Embodiment 9

A high frequency circuit according to Embodiment 9 will be explained using FIG. 10. FIG. 10 is a diagram showing the configuration of the high frequency circuit according to Embodiment 9.

As shown in FIG. 10, the high frequency circuit according to Embodiment 9 is configured to include a thick wire part 12f and an ultrathin wire part 12g, instead of the wire part 12a and the thin wire part 12b of the high frequency circuit according to Embodiment 1.

The thick wire part 12f constitutes a high temperature side wire part. The width of this thick wire part 12f is wider than that of the wire part 12a whose characteristic impedance is 50 Ω. More specifically, the cross-sectional area of the thick wire part 12f is larger than that of the wire part 12a. Because the thick wire part 12f is thus formed in such a way as to have a wide width, the thick wire part has a parallel capacitive characteristic. Further, the thick wire part 12f has a characteristic impedance equal to an impedance which is a reference for impedance matching in a wire 12.

The ultrathin wire part 12g constitutes a low temperature side wire part. Because of the increase in the degree of parallel capacitive characteristic which is caused by the thick wire part 12f, it is necessary to configure the ultrathin wire part 12g in such a way that the ultrathin wire part has a large degree of series inductive characteristic by making its width narrower than that of the thin wire part 12b or making its length longer than that of the thin wire part 12b. FIG. 10 shows the example in which the width of the ultrathin wire part 12g is narrower than that of the thin wire part 12b. More specifically, the cross-sectional area of the ultrathin wire part 12g is smaller than that of the thin wire part 12b.

Therefore, because in the high frequency circuit the thick wire part 12f is disposed on a high temperature side 121, the thermal resistance between a heat generation part 100 and a chip resistor 15 can be reduced, and it is therefore possible to make it easier to give off the heat generated from the heat generation part 100 via the chip resistor 15. Further, because in the high frequency circuit the ultrathin wire part 12g is disposed on a low temperature side 122, it is possible to make it difficult for the heat generated from the heat generation part 100 to escape toward the ultrathin wire part 12g.

As mentioned above, in the high frequency circuit according to Embodiment 9, the high temperature side wire part includes the thick wire part 12f having a width wider than that at the time of having a characteristic impedance equal to an impedance which is a reference for impedance matching in the wire 12, and the low temperature side wire part includes the ultrathin wire part 12g whose width is formed in such a way as to be narrow depending on the width of the thick wire part 12f. Therefore, the high frequency circuit can improve the heat dissipation characteristics of the wire 12.

### Embodiment 10

A high frequency circuit according to Embodiment 10 will be explained using FIG. 11. FIG. 11 is a diagram showing the configuration of the high frequency circuit according to Embodiment 10.

As shown in FIG. 11, the high frequency circuit according to Embodiment 10 is configured to include an inter-chip wire part 12h, instead of the inter-chip thin wire part 12e of the high frequency circuit according to Embodiment 7. The inter-chip wire part 12h constitutes a low temperature side wire part.

The inter-chip wire part 12h is disposed between a chip resistor 15a and a chip resistor 15b. The width of this inter-chip wire part 12h and the width of a wire part 12a are the same. More specifically, the cross-sectional area of the inter-chip wire part 12h and the cross-sectional area of the wire part 12a are the same. Because the inter-chip wire part 12h is thus formed in such a way as to have the same width as the wire part 12a, the inter-chip wire part has a series inductive characteristic.

Further, the inter-chip wire part 12h has a characteristic impedance equal to an impedance which is a reference for impedance matching in a wire 12, and is formed in such a way as to have a length with which parasitic components of the adjacent chip resistors 15a and 15b are cancelled out each other between the chip resistors. Therefore, the high frequency circuit can propagate the heat of the wire 12 while dispersing the heat to both an upstream side and a downstream side of the inter-chip wire part 12h in a direction of power transmission. Main parasitic components are, for example, capacitive components which are formed between the wire 12 and a ground wire 14 by the dielectrics of the chip resistors 15a and 15b.

As mentioned above, in the high frequency circuit according to Embodiment 10, the low temperature side wire part includes the inter-chip wire part 12h which is disposed between the chip resistors 15a and 15b adjacent to each other, and which has a series inductive characteristic. The inter-chip wire part 12h has a characteristic impedance equal to an impedance which is a reference for the impedance matching in the wire 12, and is formed in such a way as to have a length with which the parasitic components of the adjacent chip resistors 15a and 15b are cancelled out each other between the chip resistors. Therefore, the high frequency circuit can propagate the heat of the wire 12 to the ground wire 14 while dispersing the heat.

### Embodiment 11

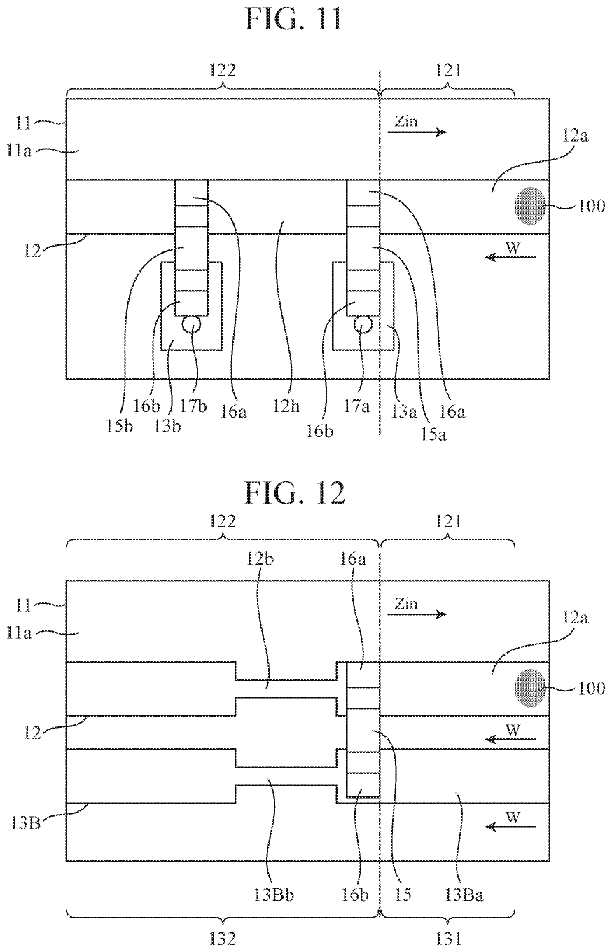

A high frequency circuit according to Embodiment 11 will be explained using FIG. 12. FIG. 12 is a diagram showing the configuration of the high frequency circuit according to Embodiment 11.

As shown in FIG. 12, the high frequency circuit according to Embodiment 11 is configured to include a wire 13B, instead of the wire 13 of the high frequency circuit according to Embodiment 1.

The wire 13B transmits high-frequency power. Therefore, the matching of impedance is needed also for the wire 13B as well as for a wire 12. This wire 13B has a second wire part 13Ba and a second thin wire part 13Bb. The second wire part 13Ba is connected to ground at a not-illustrated point.

The second wire part 13Ba constitutes a high temperature side wire part. This second wire part 13Ba has a characteristic impedance equal to an impedance which is a reference for impedance matching in the wire 13B.

The second thin wire part 13Bb constitutes a low temperature side wire part. This second thin wire part 13Bb has a thermal resistance higher than that of a chip resistor 15. The width of the second thin wire part 13Bb is narrower than that of the second wire part 13Ba. More specifically, the cross-sectional area of the second thin wire part 13Bb is smaller than that of the second wire part 13Ba. Because the second thin wire part 13Bb is thus formed in such a way as to have a narrow width, the second thin wire part has a series inductive characteristic.

The chip resistor 15 is electrically connected between the wire 12 and the wire 13B. Therefore, correspondingly to the high temperature side 121 and the low temperature side 122 of the wire 12, the wire 13B is divided into a high temperature side 131 and a low temperature side 132 with the chip resistor 15 being set as a boundary.

Therefore, the high frequency circuit can propagate the heat of the wire part 12a to the second wire part 13Ba via the chip resistor 15, and can further propagate the heat propagated to the second wire part 13Ba to the ground.

As mentioned above, the high frequency circuit according to Embodiment 11 includes: the second high temperature side wire part which is disposed on the high temperature side 131 with the chip resistor 15 being set as a boundary, and which has a characteristic impedance equal to an impedance which is a reference for the impedance matching in the wire 13B; and the second low temperature side wire part which is disposed on the low temperature side 132 with the chip resistor 15 being set as a boundary, and which has a thermal resistance higher than that of the chip resistor 15. Therefore, the high frequency circuit can improve the heat dissipation characteristics of the wire 12.

It is to be understood that an arbitrary combination of two or more of the above-mentioned embodiments can be made, various changes can be made in an arbitrary component in each of the above-mentioned embodiments, or an arbitrary component in each of the above-mentioned embodiments can be omitted within the scope of the present disclosure.

### INDUSTRIAL APPLICABILITY

The high frequency circuit according to the present disclosure can improve the heat dissipation characteristics of the first wire being in contact with the heat generation part because a chip component having a thermal conductive characteristic and an electric insulation characteristic is connected between the first wire and the second wire connected to ground, and is suitable for use as a high frequency circuit or the like.

### REFERENCE SIGNS LIST

11 board,

11a front surface,

11b rear surface,

12 wire,

12a wire part,

12b thin wire part,

12c middle wire part,

12d disconnection part,

12e inter-chip thin wire part,

12f thick wire part,

12g ultrathin wire part,

12h inter-chip wire part,

121 high temperature side,

122 low temperature side,

13, 13a, 13b, 13A, 13B wire,

13Ba second wire part,

13Bb second thin wire part,

131 high temperature side,

132 low temperature side,

14 ground wire,

15, 15a, 15b chip resistor,

16a, 16b solder part,

17, 17a, 17b via,

21 stub,

100 heat generation part,

Zin input impedance, and

W direction of power transmission.

1. A high frequency circuit comprising:
a first wire provided on a front surface of a board and being in contact with a heat generation part;
a second wire provided on the front surface of the board and connected to ground; and
a chip component connected between the first wire and the second wire and having a thermal conductive characteristic and an electric insulation characteristic, wherein
the first wire includes:
a high temperature side wire part which is disposed between the heat generation part and the chip component, and which has a characteristic impedance equal to an impedance as a reference for impedance matching in the first wire; and
a low temperature side wire part which is disposed on a low temperature side with the chip component being set as a boundary, and which has a thermal resistance higher than that of the chip component.

2. The high frequency circuit according to claim 1, wherein the low temperature side wire part includes
a thin wire part which is formed in such a way as to have a width narrower than that of the high temperature side wire part, and which has a series inductive characteristic.

3. The high frequency circuit according to claim 2, wherein the low temperature side wire part includes
a stub which is disposed on a downstream side of the thin wire part in a direction of power transmission, and which has a parallel capacitive characteristic.

4. The high frequency circuit according to claim 2, wherein the thin wire part is disposed at a connection position of the chip component.

5. The high frequency circuit according to claim 1, wherein the low temperature side wire part includes:
a middle wire part which is formed in such a way as to have a length having a characteristic impedance equal to an impedance as a reference for impedance matching in the first wire; and
a disconnection part which is disposed on a downstream side of the middle wire part in the direction of power transmission, and which has a series capacitive characteristic.

6. The high frequency circuit according to claim 1, comprising a plurality of the chip components, wherein
the high temperature side wire part and the low temperature side wire part are arranged, with a chip component which is closest to the heat generation part, out of the plurality of chip components, being set as a boundary.

7. The high frequency circuit according to claim 6, the plurality of chip components are arranged alternately on one side and the other side of the first wire set as a boundary.

8. The high frequency circuit according to claim 6, wherein the low temperature side wire part includes an inter-chip thin wire part which is formed between at least adjacent two of the plurality of chip components and with a width narrower than that of the high temperature side wire part, and which has a series inductive characteristic.

9. The high frequency circuit according to claim 1, comprising:
a ground wire which is provided on a rear surface of the board; and
multiple vias which penetrate the board and thermally connect the second wire and the ground wire, wherein
the multiple vias are connected to the second wire in such a way as to surround a connection position of the chip component.

10. The high frequency circuit according to claim 1, wherein
the high temperature side wire part includes a thick wire part having a width wider than that at a time of having a characteristic impedance equal to an impedance as a reference for impedance matching in the first wire, and
the low temperature side wire part includes an ultrathin wire part whose width is formed in such a way as to be narrow depending on the width of the thick wire part.

11. The high frequency circuit according to claim 6, wherein
the low temperature side wire part includes an inter-chip wire part which is disposed between at least adjacent two of the plurality of chip components, and which has a series inductive characteristic,
the inter-chip wire part has a characteristic impedance equal to an impedance as a reference for impedance matching in the first wire, and is formed in such a way as to have a length with which parasitic components of the at least adjacent two chip components are cancelled out each other between the at least adjacent two chip components.

12. the high frequency circuit according to claim 1, wherein
the second wire includes:
a second high temperature side wire part which is disposed on a high temperature side with the chip component being set as a boundary, and which has a characteristic impedance equal to an impedance as a reference for impedance matching in the second wire; and
a second low temperature side wire part which is disposed on a low temperature side with the chip component being set as a boundary, and which has a thermal resistance higher than that of the chip component.

13. The high frequency circuit according to claim 1, wherein
the chip component is a chip resistor, and
a resistance value of the chip resistor is larger than a value of an input impedance of the high temperature side wire part.

14. The high frequency circuit according to claim 1, wherein
the chip component is a chip capacitor, and
capacitance of the chip capacitor is smaller than that of the first wire.
